(19) United States
(12) Patent Application Publication
(10) Pub. No.: US 2001/0026014 A1
(43) Pub. Date: Oct. 4, 2001

(54) Semiconductor device

(76) Inventors: Noriaki Sakamoto, Gunma (JP); Yoshiyuki Kobayashi, Gunma (JP); Junji Sakamoto, Gunma (JP); Shigeaki Mashimo, Gunma (JP); Katsumi Okawa, Gunma (JP); Eiju Maehara, Gunma (JP); Kouji Takahashi, Gunma (JP)

Correspondence Address: CHRIS T. MIZUMOTO, Fish & Richardson P.C., Suite 2800, 45 Rockefeller Plaza, New York, NY, 10111, US

(21) Appl. No.: 09/810,105

(22) Filed: Mar. 16, 2001

(30) Foreign Application Priority Data
Mar. 28, 2000 (JP) P. 2000-088735

(51) Int. Cl. H01L 23/48; H01L 23/52

(52) U.S. Cl. 257/690

(57) ABSTRACT

After a trench 14 has been formed in a conductive foil 60, a circuit element is mounted on the conductive foil 60. The surface of the structure is covered with insulating resin 10 using the conductive foil 60 as a supporting board. After the structure has been turned upside down, this time, the conductive foil is polished using the insulating resin 10 as a supporting board so that it is separated into conductive paths 11. Therefore, a semiconductor device 13 in which the conductive paths 11 and the semiconductor chip 12 are supported by the insulating resin 10 can be realized with no supporting board. In addition, since the semiconductor chip 12 is thermally coupled with a conductive path 11A, heat generated in the semiconductor chip 12 can be radiated externally.

### BACKGROUND OF THE INVENTION

1. Field of the Invention

This invention relates to a semiconductor device, and more particularly to a semiconductor device in which a wiring is extended from the outside of a semiconductor chip to the rear surface thereof and an external connecting electrode formed on the rear surface of the semiconductor chip.

2. Description of the Related Art

In recent years, adoption of an IC package to a portable appliance or a small-sized high-density mounted appliance has been developed. As a result, the IC package and the concept of its mounting are changing greatly. The details are described in “CPS GIJUTU TO SORE O SASAERU JISSOU ZAIRYOU/SOUTI” which is a special feature article in the Journal “DENSI ZAIRYOU (1998.9. PP22-).

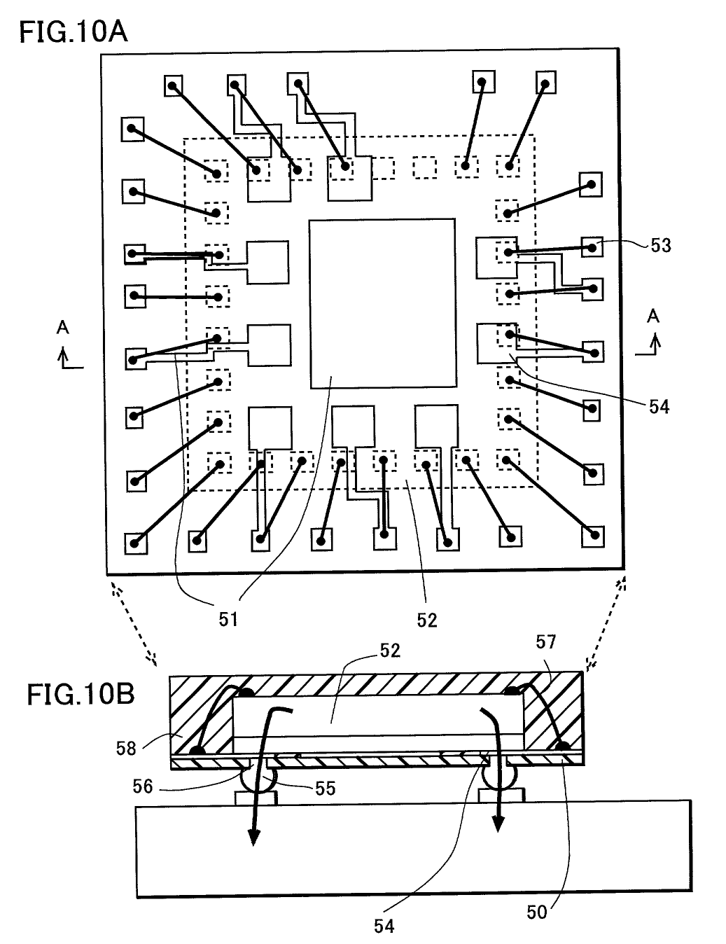

FIG. 10 shows a conventional package structure with a flexible sheet 50 serving as an interposer board on which copper foil patterns 51 are bonded through an adhesive. An IC chip is fixed to the copper foil patterns 51. Bonding pads 53 are formed around the IC chip. Pads 54 for connecting solder balls are formed via wirings integrally to the bonding pads. Solder balls 55 are formed on the pads 54 for connecting the solder balls.

On the rear side of each of the pads 54 for connecting the solder balls, an opening 56 is made in the flexible sheet. The solder ball 56 is formed through the opening 56. Using the flexible sheet as a board, the entire structure is sealed by insulating resin.

However, the above package structure cannot radiate heat sufficiently during driving because the entire structure is sealed by the insulating resin 58, the flexible sheet 50 is formed on the rear surface of the IC chip 52, and a thermal conduction path made of a material with good thermal conductivity is composed of the metallic wire 57, copper foil pattern 51 and solder ball 55. Therefore, the temperature of the IC chip 52 rises during the driving so that a sufficient driving current cannot pass through the chip.

Further, because of a difference in the thermal expansion coefficient between the insulating resin 58 and the IC chip 52, when the insulating resin is cooled from the melting point of the insulating resin to normal temperature, contraction force is applied to the insulating resin 58. Such contraction force causes the ends of the package to be lifted. This gives rise to a change of the external size of the package and makes it impossible to maintain the horizontal plane thereof. As a result, an unexpected trouble might occur when the package is mounted on a mounting board.

### SUMMARY OF THE INVENTIION

This invention has been accomplished in view of various problems described above.

First, this invention solves the problem by a semiconductor device comprising:

a plurality of conductive paths which are electrically separated from one another by a trench;

a semiconductor chip fixed on a first conductive path having a die pad shape of the plurality of conductive paths;

connecting means for connecting a bonding electrode of the semiconductor chip and a second conductive path having a bonding pad shape; and

insulating resin which covers the semiconductor chip, is embedded in the trench among the plurality of conductive paths and supports and integrally supports the conducive paths with their rear surface exposed,

wherein the second conductive path is formed outside the semiconductor chip and an external connecting pad is provided through a wiring extended from the second conductive path to the rear surface of the semiconductor chip.

Secondly, this invention solves the problems by a semiconductor device comprising:

a plurality of conductive paths which are electrically separated from one another by a trench;

a semiconductor chip fixed on a first conductive path having a die pad shape of the plurality of conductive paths;

connecting means for connecting a bonding electrode of the semiconductor chip and a second conductive path having a bonding pad shape; and

insulating resin which covers the semiconductor chip, is embedded in the trench among the plurality of conductive paths and supports and integrally supports the conducive paths with their rear surface exposed,

wherein the first conductive path has a smaller size than that of the rear surface of the semiconductor chip,

the second conductive path is formed outside the semiconductor chip, and

a third conductive path having a shape of an external connecting pad is provided through a wiring extended from the second conductive path to the rear surface of the semiconductor chip, the third conductive path has a larger size than that of the second conductive path.

Thirdly, this invention solves the problem by a semiconductor device comprising:

a plurality of conductive paths which are electrically separated from one another by a trench;

a semiconductor chip fixed on a first conductive path having a die pad shape of the plurality of conductive paths;

connecting means for connecting a bonding electrode of the semiconductor chip and a second conductive path having a bonding pad shape; and

insulating resin which covers the semiconductor chip, is embedded in the trench among the plurality of conductive paths and integrally supports the conducive paths with their rear surface exposed,

wherein the first conductive path is provided on the rear surface of the semiconductor chip to have a size smaller than that of the semiconductor chip;

the second conductive path is provided in plurality outside the semiconductor chip, one of the plurality of second conductive paths being formed in the form of an island and another thereof being formed integrally to a wiring extended to the rear face of the semiconductor chip, and

the wiring is formed integrally to a third conductive path having a shape of an external connecting pad provided between the periphery of the semiconductor chip and the first conductive path.

Since a bonding pad (second conductive path) on the side of a package connected to the bonding pad of the semiconductor chip is arranged outside the semiconductor chip, the external connecting pad can be arranged on the rear surface of the semiconductor chip which provides a vacant region. Therefore, the area where the external connecting pad can be arranged can be extended to increase the size of the pad.

Since the semiconductor chip is coupled with the first conductive path exposed to the rear surface of the package, heat generated in the semiconductor chip can be radiated externally through the first conductive path.

Since the semiconductor device can provide conductive paths separated individually from one another, warp which is generated owing to the difference in a thermal expansion coefficient between them and the supporting board can be removed.

Namely a semiconductor device of the present invention comprises:

a plurality of conductive paths which are electrically separated from one another by a trench;

a semiconductor chip connected with at least one of said conductive paths; and

insulating resin which covers said semiconductor chip, is embedded in the trench among said plurality of conductive paths and supports and integrally supports the conducive paths, rear surface of which are at least partially exposed from the insulating resin,

wherein at least one of said conductive paths is connected with said semiconductor chip at external position of a periphery of said semiconductor chip and extends to the rear surface of said semiconductor chip to be an external terminal.

The semiconductor chip can be connected with said conductive path through bonding wire, or be directly connected with said conductive path.

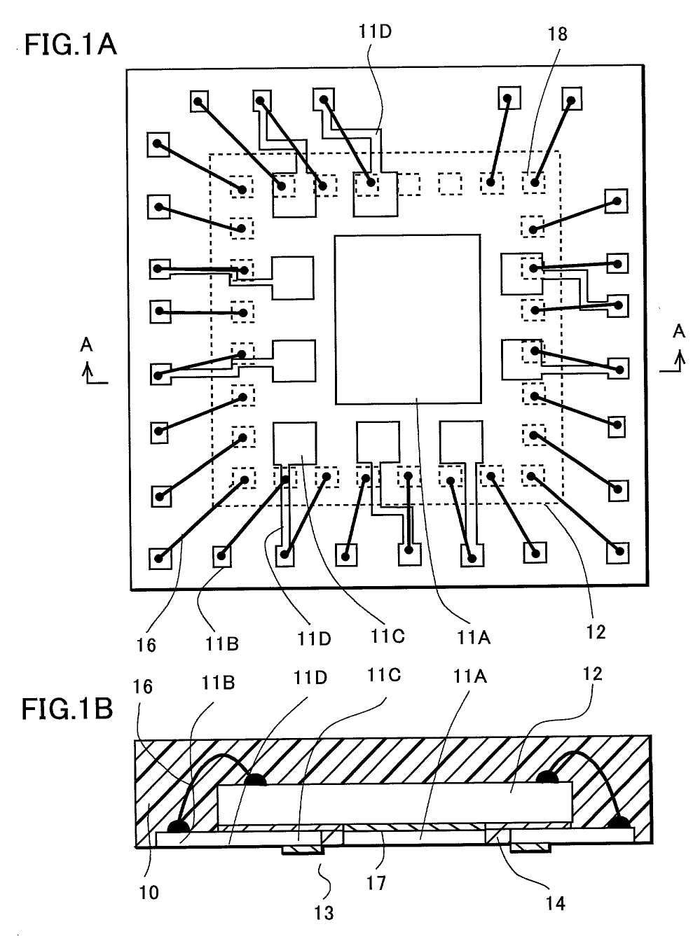

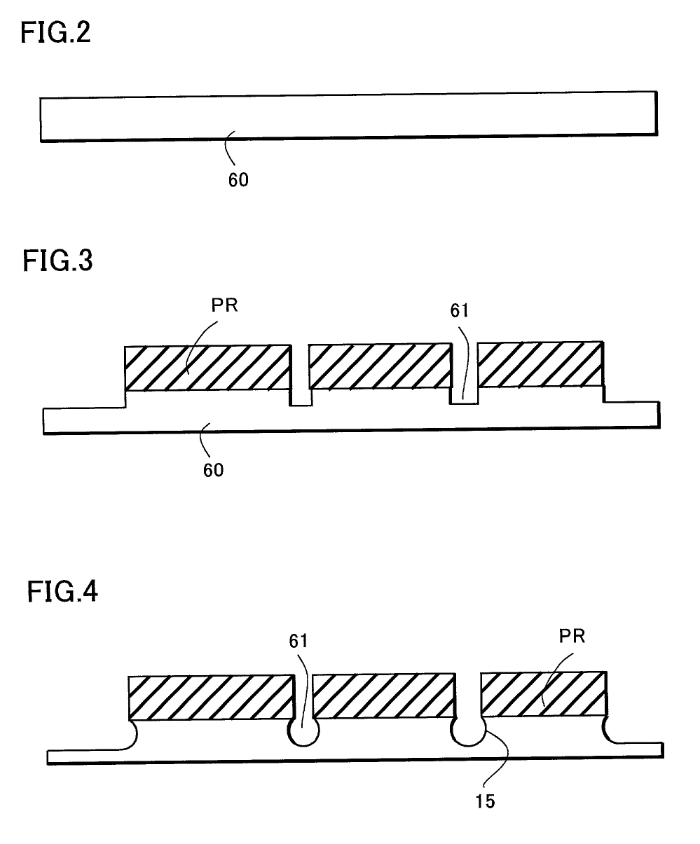

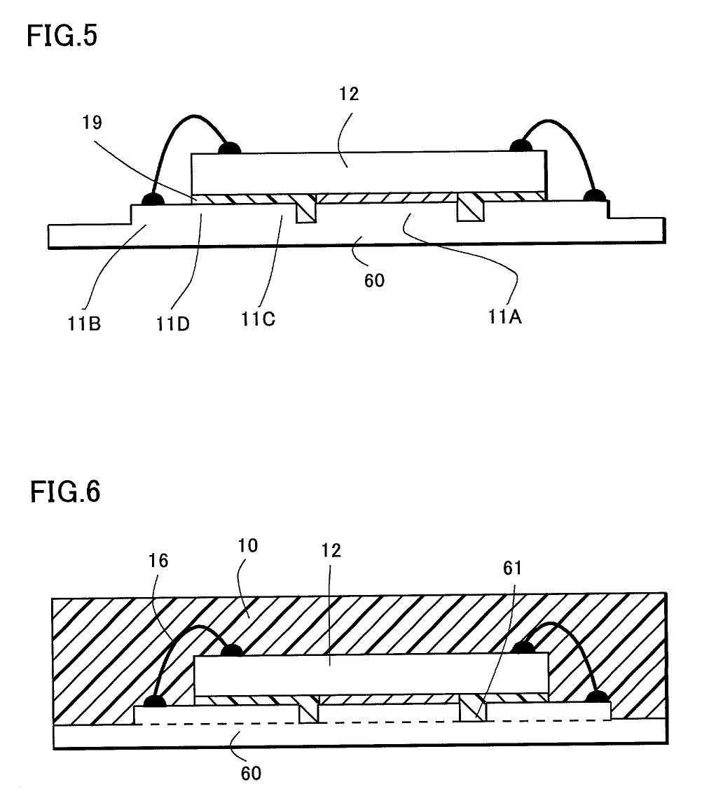

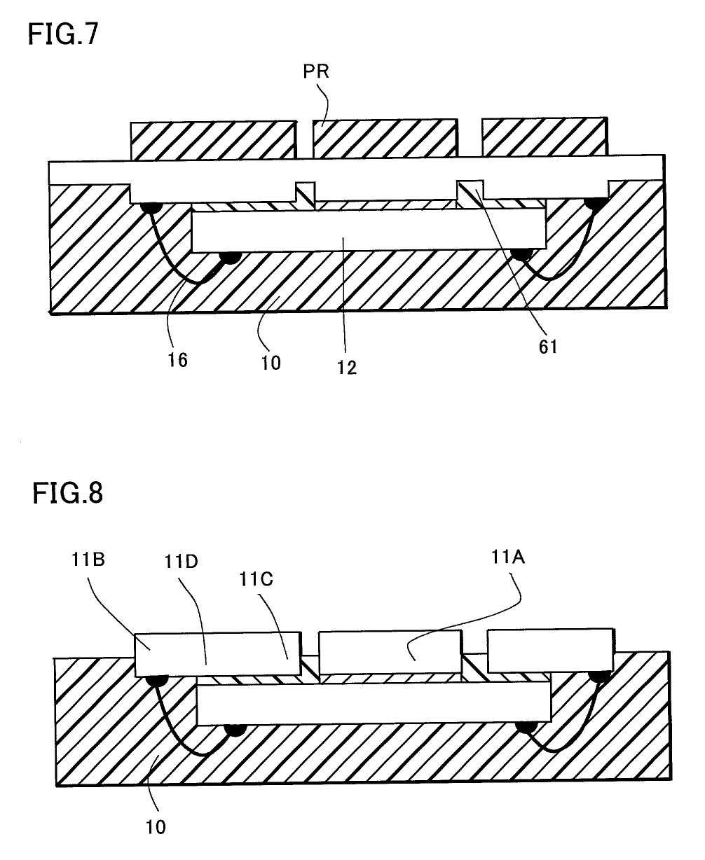

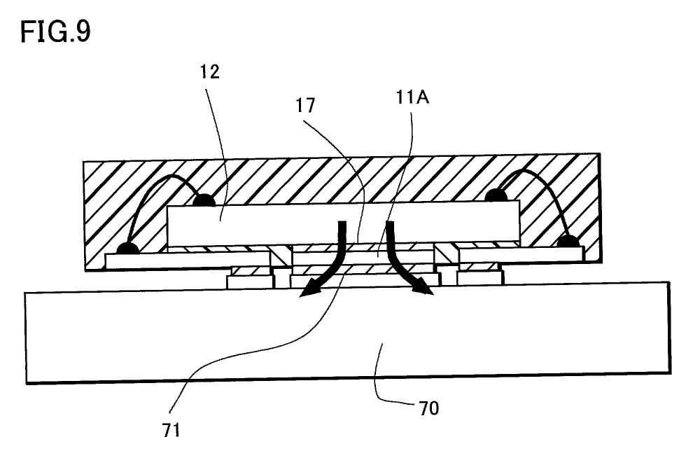

### DESCRIPTION OF THE RELATED ART

[FIG. 1] FIG. 1 is a view for explaining a semiconductor device according to this invention.

[FIG. 2] FIG. 2 is a view for explaining a method of manufacturing a semiconductor device according to this invention.

[FIG. 3] FIG. 3 is a view for explaining a method of manufacturing a semiconductor device according to this invention.

[FIG. 4] FIG. 4 is a view for explaining a method of manufacturing a semiconductor device according to this invention.

[FIG. 5] FIG. 5 is a view for explaining a method of manufacturing a semiconductor device according to this invention.

[FIG. 6] FIG. 6 is a view for explaining a method of manufacturing a semiconductor device according to this invention.

[FIG. 7] FIG. 7 is a view for explaining a method of manufacturing a semiconductor device according to this invention.

[FIG. 8] FIG. 8 is a view for explaining a method of manufacturing a semiconductor device according to this invention.

[FIG. 9] FIG. 9 is a view for explaining a method of manufacturing a semiconductor device according to this invention.

[FIG. 10] FIG. 10 is a view for explaining a conventional mounting structure for a circuit device.

### DESCRIPTION OF THE PREFERRED EMBODIMENTS

Embodiment 1 Explaining the Semiconductor Device

Now referring to FIG. 1, an explanation will be given of the structure of the semiconductor device according to this invention. FIG. 1A is a plan view of the semiconductor device and FIG. 1B is a sectional view taken in line A-A.

FIG. 1 shows a semiconductor device 13 having conductive paths 11A-11D which are embedded in insulating resin 10 and supported by the insulating resin. Incidentally, the first conductive path 11A serves as a die pad to which a semiconductor chip 12 is fixed. The side wall of each of the conductive paths 11A-11D may be curved. The details will be described later with reference to FIG. 4.

The structure of the semiconductor device 13 shown in FIG. 1 is composed of three components: the semiconductor chip 12, plurality of conductive paths 11A-11D and insulating resin in which the conductive paths 11A-11D are embedded. A trench which is filled with the insulating resin 10 is provided among the conductive paths 11A-11D. The conductive paths are supported by the insulating resin 10.

The insulating resin may be thermosetting resin such as epoxy resin or thermoplastic resin such as polyimide resin and polyphenylene sulfide. The insulating resin may be any resin as long as it is resin hardened using a mold, or can be covered by dipping or applying. The conductive paths 11A-11D may be a conductive foil mainly made of Cu, Al, an alloy such as Fe—Ni, or laminated plate such as Al—Cu plate or Cu—Al—Cu. The other conductive material may be used. Particularly, the conductive material which can be etched or evaporated by laser is preferably used.

This invention, in which the trench 14 is also filled with the insulating resin 10 and the conductive paths 11A-11D are supported by the insulating resin 10, has a feature that the conductive paths 11A-11D are prevented from coming off.

The conductive path may be subjected to anisotropic etching by dry etching or wet etching so that the side wall of the conductive path has a curved structure 15 to provide the anchor effect. Thus, the structure can be realized in which the conductive paths 11A-11D do not come off from the insulating resin 10.

In addition, the first conductive path 11A is exposed to the rear surface of the package made of the insulating resin 10 and directly fixed to the rear surface of the semiconductor chip 12 by a brazing material. For example, when the first conductive path 11A is fixed to an electrode on amounting board, the heat generated from the semiconductor chip 12 can be radiated externally through the first conductive path 11A so that a temperature rise in the semiconductor chip 12 can be prevented. The driving current flowing through the semiconductor chip 12 can be increased correspondingly.

The connecting means for the semiconductor chip 12 may be the metallic wires 16 and brazing material 17 such as solder (or conductive paste such as Ag paste, conductive film or anisotropic conductive resin).

The semiconductor chip 12 and first conducive path 11A can be fixed to each other by insulating adhesive mixed with fillers which facilitate thermal conduction as long as no electric connection is required.

In the semiconductor device according to this embodiment, the conductive paths 11A-11D are supported by the insulating resin 10, no supporting board is required. The semiconductor device is composed of the conductive paths 11A-11D, semiconductor chip 12 and the insulating resin 10. This configuration is a feature of this invention. As described with reference to the prior art, the conventional semiconductor device, in which the conductive paths are supported by the supporting board (flexible sheet, printed board or ceramic board) or otherwise supported by a lead frame, is provided with the component which can be removed essentially is added. On the other hand, the semiconductor device according to this embodiment is constructed by a necessary and minimum number of components and requires no special supporting board. This contribute to realize a low-profile and low cost semiconductor device.

Since the bonding electrodes 18 of the semiconductor chip 12 each is connected to the one end of each the metallic wires 16, the second conductive paths 11B each connected to the other end of each the metallic wires 16 are arranged on the periphery of the semiconductor chip 12. The semiconductor chip has bonding pads prepared to correspond to a plurality of circuits. The bonding electrodes 18 are classified into I/O electrode (s) necessary to circuit A constituted using the semiconductor device 13, an I/O electrode(s) testing electrodes for evaluating the semiconductor chip, etc.

In accordance with this invention, since the semiconductor device 13 is packaged to constitute the circuit A, necessary I/O electrodes and testing electrodes are connected to the second conductive paths 11B through the metallic wires 16. Among them, the second conductive path connected to the testing electrode, which is measured in contact with a probe bar, may be small in size. The second conductive path 11B electrically connected to the I/O electrode must be large in size in view of the current capacity. Therefore, the second conductive path 11B electrically connected to the I/O electrode is extended to the rear surface of the semiconductor chip 12 through the wiring 11D, and electrically connected to the third conductive path 11C arranged on the space between the periphery of the semiconductor chip 12 and the first conductive path 11A.

The first conductive path 11A, which is made of Cu having good conductivity, may be smaller in size than that of the semiconductor chip 12. A space is formed between the first conductive path 11A and the second conductive path 11B. In this space, the third conductive path 11C having a larger size than that of the conductive path 11B can be arranged.

Since the third conductive paths 11C are arranged inside the second conductive paths 11B arranged in a ring shape, when the semiconductor device 13 is fixed to a mounting board, the following meritorious effects can be provided. Even when stress is applied to the connecting portions because of the difference in the thermal expansion coefficient between the mounting board and semiconductor device 13, since the second conductive path 11B is fixed to the electrode formed on the mounting board, the stress is difficult to act on the connecting portion between the third conductive path 11C and the electrode formed on the mounting board.

The surface of the conductive paths 11 may be substantially flush with that of the trench 14 or convex therefrom. Where there is no step between the electrodes 11 and the insulating resin on the rear surface of the semiconductor device, the semiconductor device 13 can be shifted horizontally as it is. Namely, where the semiconductor is fixed to the mounting board by the brazing material, it is self-aligned on the mounting board because of the surface tension of the brazing material. Where the electrodes 11A to 11D are made convex from the insulating resin, the wirings are not short-circuited with the conductive paths on the mounting board even when the brazing material or flux is scattered.

In a case of conventional device shown in FIG. 10, as the case may be, the semiconductor chip is sealed by die molding method using the thermosetting resin or thermoplastic resin as insulating resin 58. In this step, heat treatment is carried out to harden the insulating resin 58. During the molding, the insulating resin has a large linear expansion coefficient of 30 ppm/° C. In this case, because of its difference from that (3 ppm/° C.) of the Si in the IC chip 52, contraction force is acted on the insulating resin 58 owing to the temperature drop by cooling from the treatment temperature to the normal temperature.

When the insulating resin 68 was cooled after having been molded, because of the above contraction force, edges of the semiconductor device were lifted. This gave rise to the change in the external size (warping) of the semiconductor device.

Because the supporting board for supporting the conductive paths 11A-11D is not adopted, and the conductive paths 11A-11D are individually separated so that the insulating resin is arranged among them, the contraction force caused by contraction of the insulating resin is dispersed. Further this invention can approximate the thermal expansion coefficient of the area located on the rear surface of the semiconductor device 13 to that of the insulating resin, thereby suppressing the warping can be performed.

Embodiment 2 Explaining the Method of Manufacturing a Circuit Device

Referring to FIGS. 2-9, an explanation will be given of the method of manufacturing the semiconductor device 13.

As seen from FIG. 2, a sheet-like conductive foil 60 is prepared. The material of the conductive foil 60 is selected from the standpoint of the properties of deposition, bonding and plating of a brazing material. The material of the conductive foil may be a conductive foil mainly made of Cu, a conductive foil mainly made of Al, a conductive foil made of an alloy such as Fe—Ni, or laminated plate such as Al—Cu plate or Cu—Al—Cu.

The thickness of the conductive foil is preferably 10 μm-300 μm. In this embodiment, the conductive foil having a thickness of 70 μm (2 ounce) was adopted. However, the thickness may be basically not smaller 300 μm or not larger 10 μm as long as a trench 61 which is more shallow than the thickness of the conductive foil 60 can be formed.

The sheet-like conductive foil 60 may be prepared as a roll wound with a prescribed width which is transported in respective steps described later. Otherwise, the sheet-like conductive foil 60 may be prepared as the foils each cut in a prescribed size which are transported to the respective steps described later.

There is a subsequent step of removing the conductive foil 60 other than at least areas constituting the conductive paths 11A-11D to have a thickness smaller than that of the conductive foil. The semiconductor chip 12 is mounted on the conductive paths 11A-11D formed in this removal step. Further, there is another step of covering the trench 61 and conductive foil with insulating resin 10.

First, as seen from FIG. 3, photoresist PR (etching resistant mask) is formed on the conductive foil 60 of Cu. The photoresist PR is patterned so that the conductive foil 60 other than the areas constituting the conductive paths 11A-11D are exposed. Etching is made through the photoresist.

In the case shown in FIG. 3, the trench 61 was formed. However, in the method according to this embodiment, the conductive foil is etched non-anisotropically by wet etching or dry etching. The side wall of the trench 61 is coarse and curved as shown in FIG. 4. On the other hand, the anisotropic etching or metal evaporation by laser gives a straight side wall of the trench 61 as shown in FIG. 3. The trench 61 separated by etching has a depth of about 50 μm.

In the case of wet etching, the etchant may be ferric chloride or cupric chloride. The above conductive foil is dipped within this etchant, or otherwise the etchant is subjected to showerring in which the etchant is supplied from a direction perpendicular to the substrate surface .

Particularly, as seen from FIG. 4, immediately beneath the photoresist PR serving as an etching mask, the etching is difficult to advance laterally. At a deeper position, the etching advances laterally. As seen from FIG. 4, at a more upward position from a certain position of the side wall of the trench 61, the corresponding opening has a smaller diameter. Thus, an inverted tapering structure is formed to provide an anchor structure. Since the showering is adopted, the etching advances in a direction of depth, and is suppressed in a lateral direction, thereby remarkably revealing the anchor structure. Further since in the showering the etchant is supplied from a direction perpendicular to the substrate surface, high accuracy of pattern can be obtained.

In the case of dry etching, the etching can be carried out anisotropically or non-anisotropically. At present, it is said that Cu cannot be removed by reactive ion etching, but removed by sputtering. The etching can be carried out anisotropically or non-anisotropically according to the condition of sputtering.

Incidentally, in FIGS. 3 and 4, a conductive film resistant to the etching solution may be selectively used in place of the photoresist PR. The conductive film selectively covered on the area constituting the conductive path serves as an etching protection film. In this case, the trench can be etched without using the photoresist. The material of the conductive film may be Ag, Au, Pt or Pd. In addition, these conductive films resistant to the etching can be used as a die pad or bonding pad as they are.

For example, the Ag film can be coupled with Au and also coupled with a brazing material. Therefore, where the rear surface of the chip is covered with the Au film, the chip can be thermally crimped on the Ag film on the conductive path 51 as it is. Otherwise, the chip can be fixed to the Ag film through the brazing material such as solder. Further, since an Au wire can be coupled with the conductive film of Ag, wire bonding can be carried out. Therefore, these conductive films can be used as a die pad or bonding pad as they are.

As shown in FIG. 5, there is a step of mounting the semiconductor chip 12 so as to be electrically connected to the conductive foil 60 with the trench 61 formed.

The semiconductor chip 12 may be a semiconductor element such as a transistor, a diode, an IC chip.

In this embodiment, a bare IC chip 12 is die-bonded on the first conductive path 11A which has been formed by half-etching. The bonding electrode of the IC chip is connected to the second conductive path 11B through a connecting means (e.g. metallic wire) which is fixed by ball-bonding using thermal crimping or wedge bonding using an ultrasonic wave.

In order to prevent the short-circuit between the rear surface of the semiconductor chip 12 and the wiring 11D and between the rear surface of the semiconductor chip 12 and the third conductive path 11C, an insulating material 19 is formed therebetween. The insulating material 19 is formed in such a fashion that the insulating resin is formed on the semiconductor chip 12 or conductive foil 60 is removed at the area corresponding to the first conductive path 11A.

As shown in FIG. 6, there is a step of depositing the insulating resin 10 on the conductive foil 60 and separating trench 61. This can be realized by transfer molding, injection molding or dipping. Specifically, the thermal setting resin such as epoxy resin can be realized by transfer molding, and the thermoplastic such as polyimide resin or polyphenylene sulfide can be realized by injection molding.

In this embodiment, the thickness of the insulating resin 10 covered on the front surface of the conductive foil 60 is adjusted with a thickness of about 100 μm above from the top of the connecting means. This thickness may be larger or smaller in view of the strength of the circuit device.

The feature of this step resides in that the conductive foil 60 constituting the conductive paths 11 serves as a supporting board until the insulating resin 10 is covered. Conventionally, as shown in FIG. 10, the supporting board 50 which is not essentially necessary is adopted to form the conductive paths 51. In contrast, the conductive foil 60 constituting a supporting board is a necessary material as an electrode material. This provides a merit of capable of saving the constituent material and reducing the production cost of the semiconductor device.

The trench 61 is formed with a depth which is smaller than the thickness of the conductive foil. Therefore, the conductive foil 60 is not separated into the individual conductive paths 11A-11D. For this reason, the conductive paths can be unitarily dealt with as a sheet-like conductive foil. In molding the insulating resin 10, this greatly facilitates its transfer thereof into a mold or its mounting into the mold.

Where the trench 61 having a curved structure 15 is filled with the insulating resin 10, this portion provides the anchor effect. Therefore, the insulating resin 10 can be prevented from being come off and the conductive paths which will be separated in a later step can be prevented from falling out.

Subsequently, there is a step of chemically or physically removing the rear surface of the conductive foil 60 so that the conductive foil is separated into the conductive paths 11. This removal step can be realized by grinding, polishing, etching, metal evaporation by laser.

For example, the entire rear surface is cut by about 30 μm using a polishing or grinding device so that the insulating resin 10 is exposed from the trench 61. In FIG. 6, the exposed surface is indicated by dotted line. As a result, the conductive foil 60 is separated into conductive paths 51 each having a thickness of about 40 μm. Further the following step can be used. At first, the entire surface of the conductive foil 60 may be wet-etched. And wet-etching is stopped before the insulating resin 10 is exposed. At last by polishing or grinding the entire surface can be removed so as to expose the insulating resin 50. Further, as seen from FIG. 7, using as a mask, photoresist PR formed on the rear surface of the semiconductor device corresponding to the conductive paths 11A-11D, the conductive paths 51 may be formed by etching.

Thus, a structure is completed in which the surface of the conductive paths is exposed from the insulating resin 10. The trench 61 is formed into the trench in FIG. 1. When polishing is done to reach dotted line in FIG. 6, the surface of the insulating resin 10 is flush with that of the conductive paths 11. Therefore, the rear surface of the semiconductor device becomes flat. When the photoresist PR is adopted, as seen from FIG. 8, the conductive paths 11A-11D protrude from the rear surface of the insulating resin 10.

Where the rear surface of the conductive paths 11 is to be covered with a conductive film, the rear surface of the conductive foil may be beforehand covered with the conductive film. In this case, the areas corresponding to the conductive paths may be selectively covered with the conductive film. This can be made by e.g. plating. This conductive film is preferably made of the material resistant to etching. Where the conductive film is adopted, the conductive paths can be separated by only etching without polishing.

Finally, as the occasion demands, the exposed conductive paths 11 are covered with a conductive material such as solder to complete a circuit device. As seen from FIG. 9, the circuit device is mounted on a mounting board 70.

The mounting board 70 is provided with electrodes corresponding to the conductive paths 11A-11D. These electrodes can be electrically coupled with the conductive paths through a brazing material 71.

Arrows in FIG. 9 represent that heat generated in the semiconductor chip 12 is conducted to the mounting board 70 through the first conductive path 11A. Where the supporting board (flexible sheet) 50 is adopted as in the conventional structure shown in FIG. 10, since it has high thermal resistance, the semiconductor chip generates heat so that a high driving current cannot be obtained. On the other hand, in this invention, the rear surface of the semiconductor chip 12 is fixed to the conductive patterns of the mounting board 70 through the brazing material 17, first conductive path 11A and brazing material 71. Therefore, the heat generated in the semiconductor chip 12 can be conducted to the mounting board. This prevents the temperature rise in the semiconductor chip 12 so that the driving current can be increased correspondingly.

Incidentally, in the method according to this invention, only a chip (unit) integrated with semiconductor elements such a transistor or chip resistor is mounted on the conductive foil 60. However, these units may be arranged in a matrix. The units of plurality of circuit elements may be arranged in the matrix. A plurality of semiconductor chips, passive elements and wirings for electrically connecting these components may be formed by the above conductive paths to complete the circuit having a desired function. These circuits may be arranged in the matrix. In this case, an additional step of the semiconductor device into individual devices must be performed by the dicing means.

As seen from FIG. 6, where the conductive foil 60 is bonded to the substantially entire region of the rear surface of the semiconductor device 13, the semiconductor device 13 greatly warps owing to a difference in the thermal expansion coefficient between the conductive foil 60 and the insulating resin 10. However, the conductive foil is thereafter separated into the conductive paths 11 so that they have a smaller thickness than that of the conductive foil 60, and the insulating resin is embodied among these conductive paths. Such a structure suppresses the bimetal effect to reduce the warping.

The feature of the method according to this invention resides in that the conductive paths 11 are separated using the insulating resin 10 as a supporting board. The insulating resin 10 is the material into which the conductive paths are to be embedded. Unlike the conventional manufacturing method shown in FIG. 3, the supporting board 5 which is redundant is not required. Therefore, according to the manufacturing method according to this invention, the semiconductor device can be manufactured with a necessary and minimum number of materials, thereby reducing the production cost. As understood from the description hitherto made, in this invention, the first conductive path 11A, which is made of the material with good thermal conductivity, may be smaller than the semiconductor chip. Therefore, a space can be provided between the first conductive path and the second conductive path. Thus, the third conductive path which is larger than the second conductive path in their size.

Since the third conductive paths are arranged so that they are surrounded by the second conductive paths arranged in a ring shape, even when stress is applied to the connecting portions because of the difference in the thermal expansion coefficient between the mounting board and semiconductor device, the stress is difficult to act on the connecting portion between the third conductive path and the electrode formed on the mounting board.

Since the semiconductor device is provided with a plurality of conductive paths electrically separated from one another, a semiconductor chip fixed to the desired conductive path and the insulating resin which covers the semiconductor chip, is embedded in the trench among the conductive paths and integrally supports the conducive paths with only their rear surface exposed, it can be manufactured by necessary and minimum conductive paths and insulating resin, thereby completing a circuit device with no redundant resource. Therefore, since there is no redundant component until the circuit device is completed, its production cost can be greatly reduced. Since the thickness of the covering insulating resin and the conductive foil is optimized, a greatly miniaturized and low-profile and light-weight circuit device can be realized.

Since only the rear surface of the conductive paths is exposed from the insulating resin, it can be directly connected to an external device. This makes it unnecessary to use the supporting board having a conventional structure as shown in FIG. 10.

Further, since the semiconductor chip is directly fixed to the conductive paths, and the rear surface of the conductive paths is exposed, the heat generated form the circuit element can be directly conducted to the mounting board. Particularly, this heat radiation permits the driving capability of the semiconductor chip to be improved.

Where the semiconductor device has a flat surface since the surface of the trench is substantially flush with that of the conductive paths, it can be horizontally shifted as it is. This makes it very easy to correct displacement of the lead wires.

Where the side of the conductive path is curved, the anchor effect can be produced, thereby preventing the warp or coming off of the conductive paths.

Further resin layer can be formed on the rear surface of the chip.

What is claimed is:

1. A semiconductor device comprising:
a plurality of conductive paths which are electrically separated from one another by a trench;
a semiconductor chip fixed on a first conductive path having a die pad shape of said plurality of conductive paths;
connecting means for connecting a bonding electrode of said semiconductor chip and a second conductive path having a bonding pad shape; and
insulating resin which covers said semiconductor chip, is embedded in the trench among said plurality of conductive paths and supports and integrally supports the conducive paths with their rear surface exposed,
wherein said second conductive path is formed outside said semiconductor chip and an external connecting pad is provided through a wiring extended from said second conductive path to the rear surface of said semiconductor chip.

2. A semiconductor device according to claim 1
wherein said first conductive path has a smaller size than that that of the rear surface of said semiconductor chip,
said second conductive path is formed outside said semiconductor chip, and
a third conductive path having a shape of an external connecting pad is provided through a wiring extended from said second conductive path to the rear surface of said semiconductor chip, said third conductive path has a larger size than that of said second conductive path.

3. A semiconductor device according to claim 1
wherein said first conductive path is provided on the rear surface of said semiconductor chip to have a smaller size than that of said semiconductor chip;
said second conductive path is provided in plurality outside said semiconductor chip, one of said plurality of the second conductive paths being formed in the form of an island and another thereof being formed integrally to a wiring extended to the rear face of said semiconductor chip, and
said wiring is formed integrally to a third conductive path having a shape of an external connecting pad provided between the periphery of said semiconductor chip and said first conductive path.

4. A semiconductor device according to claim 1, wherein said first conductive path is coupled with said semiconductor chip through a conductive material.

5. A semiconductor device according to claim 2, wherein an insulating material is provided between said wiring extended to the rear surface of said semiconductor chip and said semiconductor chip or between said third conductive path and said semiconductor chip.

6. A semiconductor device according to claim 1, wherein an insulating material is provided over the entire region of a rear surface of said semiconductor chip.

7. A semiconductor device according to claim 1, wherein said connecting means is a metallic wire.

8. A semiconductor device according to of claim 1, wherein the side of each of said conductive paths is curved to mate with said insulating resin.

9. A semiconductor device according to of claim 1, wherein said conductive paths are made of a conductive foil selected from the group consisting of copper, aluminum and iron-nickel.

10. A semiconductor device according to of claim 1, wherein the upper surface of said conductive paths is covered with a metallic material different from that of said conductive paths.

11. A semiconductor device according to claim 10, wherein said conductive film is made of the material selected from the group consisting of nickel, silver and gold.

12. A semiconductor device according to of claim 1, wherein said first conductive path is coupled with a conductive pattern formed on a mounting board through a conductive material.

13. A semiconductor device according to claim 3, wherein said second conductive path which is formed in an island is a test pin.

14. A semiconductor device comprising:
a plurality of conductive paths which are electrically separated from one another by a trench;
a semiconductor chip connected with at least one of said conductive paths; and
insulating resin which covers said semiconductor chip, is embedded in the trench among said plurality of conductive paths and supports and integrally supports the conducive paths, rear surface of which are at least partially exposed from the insulating resin,
wherein at least one of said conductive paths is connected with said semiconductor chip at external position of a periphery of said semiconductor chip and extends to the rear surface of said semiconductor chip to be an external terminal.

15. A semiconductor device according to claim 14,
wherein said semiconductor chip is connected with said conductive path through bonding wire.

16. A semiconductor device according to claim 14,
wherein said semiconductor chip is directly connected with said conductive path.
